(19) United States
(12) Patent Application Publication
(10) Pub. No.: US 2024/0357876 A1
(43) Pub. Date: Oct. 24, 2024

(54) DISPLAY PANEL, METHOD FOR PREPARING SAME, AND DISPLAY DEVICE

(71) Applicants: Yunnan Invensight Optoelectronics Technology Co., Ltd., Yunnan (CN); BOE Technology Group Co., Ltd., Beijing (CN)

(72) Inventors: Yunlong LI, Beijing (CN); Pengcheng LU, Beijing (CN); Wei LIU, Beijing (CN); Dacheng ZHANG, Beijing (CN); Xiaochuan CHEN, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 18/682,940

(22) PCT Filed: Apr. 24, 2023
(86) PCT No.: PCT/CN2023/090262

§ 371 Date: Feb. 12, 2024

(30) Foreign Application Priority Data
Apr. 27, 2022 (CN) 202210452974.8

(51) Int. Cl. H10K 59/126; H10K 59/12; H10K 59/131

(52) U.S. Cl. CPC H10K 59/126; H10K 59/1201; H10K 59/131

(57) ABSTRACT

Provided is a display panel, including: a substrate, a light-emitting structure, a light-shielding layer, and a cover plate. The substrate includes a display region and a bezel region. The bezel region surrounds the display region. The light-emitting structure is disposed on the substrate. The light-shielding layer is disposed on the substrate where the light-emitting structure is disposed, and the light-shielding layer is disposed in the bezel region. The cover plate is disposed on a side, distal from the substrate, of the light-light-shielding layer, and the cover plate includes a first plate body disposed in the display region and a second plate body extending from the first plate body to the bezel region. An orthographic projection of the second plate body on the substrate is within an orthographic projection of the light-shielding layer on the substrate.

### CROSS-REFERENCE TO RELATED APPLICATIONS

This application is a U.S. national stage of International Application No. PCT/CN2023/090262, filed on Apr. 24, 2023, which claims priority to Chinese Patent Application No. 202210452974.8, filed on Apr. 27, 2022, and entitled “DISPLAY PANEL AND PREPARATION METHOD THEREFOR, AND DISPLAY APPARATUS,” the contents of each are herein incorporated by reference in their entireties.

### TECHNICAL FIELD

The present disclosure relates to the field of display technologies, and in particular, relates to a display panel, a method for preparing the same, and a display device.

### BACKGROUND

At present, display panels are usually constructed in such a way that: a projection of a cover plate of a bezel region on a substrate is larger than a projection of a color film frame of the bezel region on the substrate for physical protection; and the projection of the color film frame of the bezel region on the substrate is larger than a projection of an auxiliary cathode of the bezel region on the substrate to ensure that the projection of the color film frame on the substrate also covers the projection of the auxiliary cathode of the bezel region on the substrate even though the color film frame shrinks inwardly after being baked, such that patterning of metals on the auxiliary cathode does not cause the light leakage.

### SUMMARY

Embodiments of the present disclosure provide a display panel, a method for preparing the same, and a display device.

According to some embodiments of the present disclosure, a display panel is provided. The display panel includes:
a substrate, wherein the substrate includes a display region and a bezel region, the bezel region surrounding the display region;
a light-emitting structure, wherein the light-emitting structure is disposed on the substrate;
a light-shielding layer, wherein the light-shielding layer is disposed on the substrate where the light-emitting structure is disposed, and the light-shielding layer is disposed in the bezel region;
a cover plate, wherein the cover plate is disposed on a side, distal from the substrate, of the light-light-shielding layer, and the cover plate includes a first plate body disposed in the display region and a second plate body extending from the first plate body to the bezel region, an orthographic projection of the second plate body on the substrate being within an orthographic projection of the light-shielding layer on the substrate.

In some embodiments, the display panel further includes: a color film layer, wherein the color film layer is disposed in the display region, and the color film layer extends to a border of the bezel region and the display region.

In some embodiments, the light-emitting structure includes a driver circuit layer and a light-emitting layer, wherein the driver circuit layer includes a metal wiring, and the light-emitting layer includes a first electrode layer, a pixel definition layer, a light-emitting function layer, and a second electrode layer that are stacked;
wherein the metal wiring includes an edge metal wiring disposed in the bezel region, an orthographic projection of the edge metal wiring on the substrate being within the orthographic projection of the light-shielding layer on the substrate.

In some embodiments, the display panel further includes: a first package layer and a first planarization layer that are disposed between the light-emitting layer and the color film layer;
wherein the first package layer and the first planarization layer are successively stacked along a direction away from the substrate, and the first package layer and the first planarization layer extend to the bezel region.

In some embodiments, the light-shielding layer is disposed on a side, distal from the substrate, of the first planarization layer.

In some embodiments, the light-shielding layer is a color film extension layer arranged in a same layer as the color film layer, and the light-shielding layer includes at least two layers of the color film layer of different colors.

In some embodiments, the display panel further includes a first alignment mark in the bezel region, wherein the light-emitting structure includes a plurality of sub-pixels in the display region;
wherein in a first direction, a distance between an edge of a side, distal from the display region, of the light-shielding layer and an edge of a side, proximal to the display region, of the first alignment mark is greater than a maximum size of the sub-pixel, the first direction being a direction pointing from a center of the display region towards the bezel region.

In some embodiments, the display panel further includes a second planarization layer and a second package layer that are disposed between the color film layer and the cover plate; wherein the second planarization layer and the second package layer are disposed in the display region, the second planarization layer and the second package layer are successively stacked along the direction away from the substrate, and both the second planarization layer and the second package layer extend to the bezel region; and
the light-shielding layer is disposed on a side, distal from the substrate, of the second package layer.

In some embodiments, the display panel further includes: a second alignment mark in the bezel region, wherein the second alignment mark is disposed on the side, distal from the substrate, of the light-shielding layer, and the second alignment mark is disposed on a same layer as the cover plate.

In some embodiments, the light-emitting structure includes a plurality of sub-pixels in the display region, and the display panel further includes a black matrix disposed between adjacent sub-pixels in the plurality of sub-pixels; wherein the black matrix is formed by overlaying color films of different colors; and
a width of the light-shielding layer along a first direction is greater than or equal to a width of the black matrix between the adjacent sub-pixels, the first direction being a direction pointing from a center of the display region towards the bezel region.

In some embodiments, in a case that the display panel includes the second alignment mark in the bezel region, an orthographic projection of the second alignment mark on the substrate is within the orthographic projection of the light-shielding layer on the substrate, and the orthographic projection of the second alignment mark on the substrate is not overlapped with an orthographic projection of the cover plate on the substrate.

In some embodiments, the display panel further includes an adhesive layer for package, wherein the adhesive layer covers an edge of a side, distal from the display region, of the bezel region.

In some embodiments, in a case that the display region further includes the second package layer, the adhesive layer is at least partially disposed on the side, distal from the substrate, of the second package layer.

In some embodiments, the light-shielding layer includes an edge light-shielding layer extending between a first edge of the cover plate and the adhesive layer, the first edge being an edge of a side, distal from the display region, of the cover plate.

In some embodiments, a thickness of the edge light-shielding layer in a direction parallel to the substrate is less than a thickness of a rest of the light-shielding layer other than the edge light-shielding layer in a direction perpendicular to the substrate.

In some embodiments, the adhesive layer abuts against an edge of a side, distal from the display region, of the cover plate.

In some embodiments, a light-shielding overlapping region is present between the orthographic projection of the light-shielding layer on the substrate and an orthographic projection of the adhesive layer on the substrate, and in a case that the display region further includes the first package layer, in a first direction, a width of the light-shielding overlapping region is greater than a target distance, wherein the target distance is a distance between the edge of the side, distal from the display region, of the light-shielding layer and an edge of a side, distal from the display region, of the first package layer, and the first direction is a direction pointing from a center of the display region towards the bezel region.

In some embodiments, in a first direction, a distance between the edge of the side, distal from the display region, of the light-shielding layer and an edge of a side, distal from the display region, of the cover plate is less than a distance between the edge of the side, distal from the display region, of the light-shielding layer and an edge of a side, distal from the display region, of the substrate, the first direction being a direction pointing from a center of the display region towards the bezel region.

In some embodiments, in a direction perpendicular to the substrate, the light-shielding layer includes an overlapping region overlapped with the cover plate and a non-overlapping region not overlapped with the cover plate, a thickness of the overlapping regions being less than a thickness of the non-overlapping region.

In some embodiments, the thickness of the non-overlapping region in the direction perpendicular to the substrate gradually increases along the first direction, the first direction being the direction pointing from the center of the display region towards the bezel region.

In some embodiments, the cover plate extends to an edge, distal from the display region, of the bezel region; and
in the bezel region, the orthographic projection of the light-shielding layer on the substrate is consistent with an orthographic projection of the cover plate on the substrate.

In some embodiments, in a case that the bezel region further includes the first alignment mark, a thickness of a first portion of the light-shielding layer in a direction perpendicular to the substrate gradually increases along a first direction, wherein the first portion of the light-shielding layer is a portion of the light-shielding layer whose orthographic projection on the substrate is overlapped with an orthographic projection of the first alignment mark on the substrate, and the first direction is a direction pointing from a center of the display region towards the bezel region.

In some embodiments, the display panel further includes a cathode ring in the bezel region and surrounding the display region;
wherein the light-emitting layer includes a first electrode layer, a pixel definition layer, a light-emitting function layer, and a second electrode layer that are stacked, wherein the second electrode layer extends to the bezel region and is stacked on a side, distal from the substrate, of the cathode ring, the orthographic projection of the light-shielding layer on the substrate covers an orthographic projection of the cathode ring on the substrate, and the second electrode layer is electrically connected to the cathode ring.

According to some embodiments of the present disclosure, a display device is provided. The display device includes the display panel as described above.

In some embodiments, the display device further includes a bonding region, wherein the display panel is in a substantially rectangular shape, and the bonding region is disposed on a short side of the display panel.

In some embodiments, a minimum distance between an edge, proximal to a long side of the display panel, of the bonding region and the edge of the side, distal from the display region, of the substrate is greater than a minimum distance between an edge, proximal to the long side of the display panel, of the light-shielding layer and the edge of the side, distal from the display region, of the substrate.

In some embodiments, in a first direction, a first distance of the display panel is greater than a second distance, wherein the first distance is a distance between the edge of the side, distal from the display region, of the light-shielding layer in the bezel region on the short side of the display panel and the edge of the side, distal from the display region, of the cover plate, the second distance is a distance between the edge of the side, distal from the display region, of the light-shielding layer in the bezel region on the long side of the display panel and the edge of the side, distal from the display region, of the cover plate, and the first direction is a direction pointing from a center of the display region towards the bezel region.

In some embodiments, in a case that the bezel region further includes a cathode ring surrounding the display region, in the first direction, a width of the cathode ring in the bezel region on the short side, proximal to the bonding region, of the display panel is greater than a width of the cathode ring in the bezel region on other sides, the first direction being the direction pointing from the center of the display region towards the bezel region.

In some embodiments, in the first direction, a distance between the edge of the side, distal from the display region, of the light-shielding layer in the bezel region of the display panel and the edge of the side, distal from the display region, of the cover plate is less than a minimum distance between the bonding region and the light-shielding layer.

According to some embodiments of the present disclosure, a method for preparing a display panel is provided. The method is applicable to preparing the display panel as described above. The method includes:
providing a substrate, wherein the substrate includes a display region and a bezel region, the bezel region surrounding the display region;
forming a light-emitting structure on the substrate;
forming a light-shielding layer on the substrate where the light-emitting structure is formed, wherein the light-shielding layer is disposed in the bezel region; and
disposing a cover plate on a side, distal from the substrate, of the light-shielding layer, wherein the cover plate includes a first plate body in the display region and a second plate body extending from the first plate body to the bezel region, an orthographic projection of the second plate body on the substrate being within an orthographic projection of the light-shielding layer on the substrate.

### BRIEF DESCRIPTION OF DRAWINGS

Specific embodiments of the present disclosure are described in optional detail hereinafter in conjunction with the accompanying drawings.

FIG. 1 is a structural diagram of a display panel in some practices.

FIG. 2 is a structural diagram of a display panel according to some embodiments of the present disclosure.

FIG. 3 is another structural diagram of a display panel according to some embodiments of the present disclosure.

FIG. 4 is still another structural diagram of a display panel according to some embodiments of the present disclosure.

FIG. 5 is yet still another structural diagram of a display panel according to some embodiments of the present disclosure.

FIG. 6 is a structural diagram of a display panel according to some embodiments of the present disclosure.

FIG. 7 is another structural diagram of a display panel according to some embodiments of the present disclosure.

FIG. 8 is still another structural diagram of a display panel according to some embodiments of the present disclosure.

FIG. 9 is a schematic diagram of a display device according to some embodiments of the present disclosure.

FIG. 10 is a flowchart of a method for preparing a display panel according to some embodiments of the present disclosure.

### DETAILED DESCRIPTION

The terms “on,” “formed on,” and “arranged on” as described in this disclosure may mean that one layer is directly formed or arranged on another layer, or one layer is indirectly formed or arranged on another layer, i.e., there are other layers between the two layers.

It should be noted that while the terms “first,” “second,” and the like may be used herein to describe various parts, components, elements, regions, layers, and/or portions, these parts, components, elements, regions, layers, and/or portions should not be limited by these terms. Rather, these terms are used to distinguish one part, component, element, region, layer, and/or portion from another. Therefore, for example, a first part, first component, first element, first region, first layer, and/or first portion described hereinafter may be referred to as a second part, second component, second element, second region, second layer, and/or second portion without departing from the teachings of the present disclosure.

In the present disclosure, unless otherwise defined, the term “arranged in the same layer” indicates that two layers, parts, components, elements, or portions may be formed by the same preparation process (e.g., patterning process, etc.), and the two layers, parts, components, elements, or portions are generally made of the same material. For example, two or more functional layers arranged in the same layer indicate that these functional layers arranged in the same layer may be made of the same material layer and formed by the same preparation process, which simplifies the preparation process of the display substrate.

In the present disclosure, unless otherwise defined, the term “patterning process” generally includes the steps of photoresist coating, exposing, developing, etching, and photoresist stripping. The term “one-time patterning process” indicates a process in which a patterned layer, a patterned part, or a patterned component is formed using one mask.

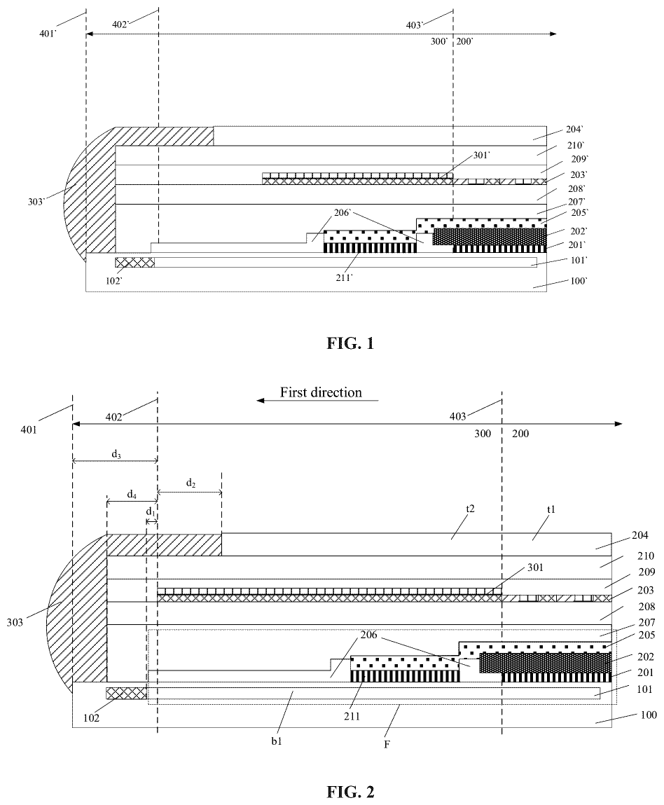

A current display panel of a silicon-based micro-display device is illustrated in FIG. 1. The silicon-based display panel includes a substrate 100′, for example, a silicon-based substrate (Si Sub), and a display region 200′ and a bezel region 300′ formed on the substrate 100′. The bezel region 300′ surrounds the display region 200′, and the display region 200′ includes a plurality of sub-pixels arranged in an array. Generally speaking, the display region 200′ includes a driver circuit layer, a pixel definition layer 206′ and a light-emitting layer, for example, for emitting white light, a cathode 205′, a first package layer 207, a first planarization layer 208′, a color film layer 203′, a second planarization layer 209′, a second package layer 210′, and a cover plate 204′ extending to the bezel region 300′, which are successively stacked on the substrate 100′. The driver circuit layer includes a metal wiring 101′ and thin film transistors (TFT) arranged in an array. The TFT includes a gate electrode, a source electrode, a drain electrode, and an active region 201′, and the light-emitting layer of each sub-pixel includes a light-emitting function layer 202′ and an anode electrically connected to the source electrode or the drain electrode.

As illustrated in FIG. 1, the metal wiring 101′, the pixel definition layer 206′, the first package layer 207, the first planarization layer 208′, the second planarization layer 209′, and the second package layer 210′ each extend to the bezel region 300′. The bezel region 300′ includes a cathode ring (which may be referred to as an annular auxiliary cathode) 211′ and a color film extension layer or color film (CF) frame 301′. In FIG. 1, a line 403′ is a boundary between the display region 200′ and the bezel region 300′, a line 402′ is an inner boundary of a cutting region (the left side of the boundary 402′ in FIG. 1 is the cuttable region), and a line 401′ is a cutting guideline. As illustrated in FIG. 1, the current design is as follows: an orthographic projection of the color film (CF) frame 301′ of the bezel region 300′ on the substrate 100′ exceeds an orthographic projection of the cathode ring 211′ of the bezel region on the substrate 100′ (i.e., an outer edge of the color film frame 301′ is closer to an outer edge of the display panel relative to an outer edge of the cathode ring 211′). An orthographic projection of the cover plate (e.g., a cover plate glass, CG) 204′ of the bezel region 300′ on the substrate 100′ exceeds the orthographic projection of the color film frame 301′ of the bezel region 300′ on the substrate 100′ (i.e., an outer edge of the cover plate 204′ is closer to the outer edge of the display panel relative to the outer edge of the color film frame 301′).

Such a design mainly takes into account that the color film frame 301′ needs to cover a brighter metal pattern on the cathode ring 211′ in order to avoid light leakage. Moreover, the color film frame 301′ may shrink inwardly after being baked, and thus the first thin film package layer 207′ breaks, which reduces the trustworthiness of the display device. Therefore, the color film frame 301′ extends outwardly more than the cathode ring 211′, and the cover plate 204′ extending outwardly more than the color film frame 301′ is mainly because of the physical protection.

The inventors have found that the above design may suffer from light leakage around the cover plate, especially for a 12-inch wafer. The reasons are as follows.
(1) The 12-inch wafer metal wiring is made of a mixture of aluminum (AL) and copper (Cu), and the metal density is increased compared to an 8-inch wafer. A portion, extending to the bezel region 300′, of the metal wiring 101′ of the driver circuit layer of the display region (AA region) 200′ produces reflected light in an uncovered region of the color film frame 301′, which leaks out of the cover plate 204′. Therefore, the uncovered region of the color film frame 301′ is brighter.
(2) For the cover plate 204′ with a thickness of, for example, about 0.5 mm, the light emitted from the display region 200′ is diffusely reflected through the cover plate 204′, and thus the light leakage occurs at the edge of the cover plate 204″.
(3) The sidewall dispensing 303′ does not completely cover plate the module sidewalls, such that light emitted from the display region 200′ leaks from the sidewalls of the cover plate 204′, such as a border of the sidewall dispensing 303′ and the cover plate 204′ of the display panel in FIG. 1.

In the current design, as illustrated in FIG. 1, for example, the color film frame 301′ has a width of 607 μm (microns), and the cover plate 204′ has a width of 865 μm in the bezel region 300′. Based on the total reflection of light and the lighting test, the light leakage includes the light that leaks out of a longitudinal gap between the cover plate 204′ and the color film frame 301′.

FIG. 2 is a structural diagram of a display panel according to some embodiments of the present disclosure. As illustrated in FIG. 2, the display panel includes:
a substrate 100, wherein the substrate 100 includes a display region 200 and a bezel region 300, the bezel region 300 surrounding the display region 200;
a light-emitting structure F, wherein the light-emitting structure F is disposed on the substrate 100;
a light-shielding layer 301, wherein the light-shielding layer 301 is disposed on the substrate where the light-emitting structure F is provided, and the light-shielding layer 301 is disposed in the bezel region 300; and
a cover plate 204, wherein the cover plate 204 is disposed on a side, away from the substrate 100, of the light-light-shielding layer 301, the cover plate 204 includes a first plate body t1 in the display region 200, and a second plate body t2 extending from the first plate body t1 to the bezel region 300, and an orthographic projection of the second plate body t2 on the substrate 100 is within an orthographic projection of the light-shielding layer 301 on the substrate 100.

The light-emitting structure F includes a plurality of sub-pixels in the display region 200.

In FIG. 2, a line 403 is a boundary between the display region 200 and the bezel region 300. A portion, in the bezel region 300, of the cover plate 204 is a portion, disposed on the left of the line 403, of the cover plate 204 in FIG. 2, a line 402 is an inner boundary of a cutting region (the left side of the boundary 402 in FIG. 2 is a cuttable region), and the line 401 is a cutting guideline.

As a result, some embodiments of the present disclosure provide a display panel, wherein the light-shielding layer 301 is disposed in the bezel region 300, and the orthographic projection of the light-shielding layer 301 on the substrate 100 covers the portion of the cover plate 204 in the bezel region. In this way, the light exiting from the display region 200 is avoided from leaking out of the periphery of the cover plate 204, and thus the display effect is improved.

In some embodiments, as shown in FIG. 2, the display panel further includes a color film layer 203. The color film layer 203 is disposed in the display region 200 and extends to a border of the bezel region 300 and the display region 200. The color film layer 203 is configured to achieve a color display. White light emitted by the sub-pixel, in some embodiments, is converted to red light, green light, or blue light after passing through a red light filter layer, a green light filter layer, or a blue light filter layer of a corresponding sub-pixel of the color film layer 203, such that the sub-pixel emitting white light is achieved as a red light sub-pixel, a green light sub-pixel, and a blue light sub-pixel, and thus an RBG triple-base color display is achieved.

In some embodiments, as shown in FIG. 2, the light-emitting structure F includes a driver circuit layer and a light-emitting layer. The driver circuit layer includes a metal wiring 101, and the light-emitting layer includes a first electrode layer (anode), a pixel-definition layer 206 for defining the sub-pixels, a light-emitting function layer 202, and a second electrode layer (cathode) 205 that are stacked.

The metal wiring 101, the pixel definition layer 206, and the light-emitting function layer 202 of the sub-pixel disposed at the edge of the display region 200 extend to the bezel region 300.

The metal wiring 101 includes an edge metal wiring b1 disposed in the bezel region 300. An orthographic projection of the edge metal wiring b1 on the substrate 100 is within an orthographic projection of the light-shielding layer 301 on the substrate 100. That is, in the bezel region 300, an orthographic projection of the metal wiring 101 on the substrate 100 is within the orthographic projection of the light-shielding layer 301 on the substrate 100. That is, the orthographic projection of the light-shielding layer 301 on the substrate 100 covers an orthographic projection on the substrate 100 of a portion of the metal wiring 101 that is within the bezel region 300. In this way, the light-shielding layer 301 is capable of covering brighter metal patterns on the metal wiring 101, such that the light leakage is avoided.

The driver circuit layer within the display region 200 further includes thin film transistors (TFT) arranged in an array. The thin film transistor TFT includes a gate electrode, a source electrode, a drain electrode, and an active region 201. The light-emitting layer of each of the sub-pixels includes the light-emitting function layer 202 and the anode electrically connected to the source electrode or the drain electrode. In the display region 200, the first electrode layer (anode) of each sub-pixel is independent, and the second electrode layer (cathode) 205 covers all sub-pixels.

In some embodiments, the pixel definition layer 206 is formed using a patterning process. Specifically, a layer of pixel definition layer material is deposited, in some embodiments, with a thickness of about 1 to 2 μm, and the pixel definition layer is formed in the display region using the patterning process. In some embodiments, the pixel definition layer is made of organic insulating materials, such as negative photoresist, polyimide, epoxy, and the like. Then, the first electrode layer (anode) and the light-emitting function layer 202 are formed at an opening (i.e., a defined pixel unit location) of the pixel definition layer 206 of the display region 200. The light-emitting function layer is, in some embodiments, an organic light-emitting function layer (EL), including, in some embodiments, a hole-injection layer (HIL), a hole-transporting layer (HTL), an electron-blocking layer (EBL), a light-emitting layer (EML), a hole-blocking layer (HBL), an electron-transporting layer (ETL), and an electron-injection layer (EIL). In some embodiments, a light-emitting device layer including the hole-injection layer (HIL), the hole-transporting layer (HTL), the electron-blocking layer (EBL), the light-emitting layer (EML), the hole-blocking layer (HBL), the electron-transporting layer (ETL), and the electron-injection layer (EIL), is formed on an anode by inkjet printing or vaporization, wherein the light-emitting device layer is made of organic materials.

In some embodiments, the substrate 100 is a silicon-based substrate, and the display panel provided in the embodiments is a silicon-based display panel.

In some embodiments, as shown in FIG. 2, the display panel further includes a first package layer 207 and a first planarization layer 208 between the light-emitting layer and the color film layer 203. The first package layer 207 and the first planarization layer 208 are successively stacked along a direction away from the substrate 100.

The first package layer 207 and the first planarization layer 208 extend to the bezel region 300.

As shown in FIG. 2, the first package layer 207 is formed on the second electrode layer (cathode) 205 of the display region 200 and extends to an outer edge of the bezel region 300, and the first planarization layer 208 is formed between the first package layer 207 and the color film layer 203 of the display region 200 and extends to the outer edge of the bezel region 300.

Optionally, in some embodiments, the light-shielding layer 301 is disposed on a side, distal from the substrate 100, of the first planarization layer 208, as shown in FIG. 2.

In some embodiments, as shown in FIG. 2, the display panel further includes a second planarization layer 209 and a second package layer 210 formed between the color film layer 203 and the cover plate 204. The second planarization layer 209 and the second package layer 210 are disposed in the display region 200, and the second planarization layer 209 and the second package layer 210 are successively stacked along the direction away from the substrate 100. The second planarization layer 209 and the second package layer 210 extend to the bezel region 300. The light-shielding layer 301 is disposed on a side, distal from the substrate 100, of the second package layer 210.

As shown in FIG. 2, the second planarization layer 209 is formed on the color film layer 203 of the display region 200 and extends to the outer edge of the bezel region 300, and the second package layer 210 is formed between the second planarization layer 209 and the cover plate 204 of the display region 200 and extends to the outer edge of the bezel region 300.

It should be noted that in some embodiments, the first planarization layer 208 and the second planarization layer 209 serve as physical protection and pass a trustworthiness test to satisfy the trustworthiness requirement.

In some embodiments, the first package layer 207 and the second package layer 210 are formed by processes such as chemical vapor deposition (CVD), atomic layer deposition (ALD), molecular layer deposition (ALD), and plasma-enhanced chemical vapor deposition (PECVD). The first package layer 207 and the second package layer 210 are formed using inorganic materials such as silicon nitride, silicon oxide, or silicon oxynitride, or organic materials such as polyimide (PI) or epoxy resin.

In some embodiments, as shown in FIG. 2, the display panel further includes a cathode ring 211 that is disposed in the bezel region 300 and surrounding the display region 200. The second electrode layer (cathode) 205 extends to the bezel region 300 and is stacked on a side, distal from the substrate 100, of the cathode ring 211. The second electrode layer (cathode) 205 is electrically connected to the cathode ring 211. The orthographic projection of the light-shielding layer 301 on the substrate 100 covers an orthographic projection of the cathode ring 211 on the substrate 100. In this way, the brighter metal patterns on the cathode ring 211 are covered, and thus the light leakage is avoided.

In some embodiments, the second electrode layer (cathode) 205 is formed on an entire surface of the display region 200 of the display panel and extends to the bezel region 300 to be electrically connected to the cathode ring 211, and the second electrode layer (cathode) 205 and the cathode ring 211 are made of, in some embodiments, metals such as Mg, Ca, Li, or Al or alloys of such metals, or metal oxides such as indium tin oxide (ITO), indium zinc oxide (IZO), or zinc tin oxide (ZTO), or organic materials with conductive properties, such as poly (3,4-ethylene dioxythiophene)/poly (styrene sulfonate) (PEDOT/PSS).

In some embodiments, the display panel further includes a black matrix between adjacent sub-pixels. The black matrix is formed by overlaying color films of different colors, such as an overlap of a red light filter layer and a green light filter layer. The red light filter layer allows only red light with a wavelength ranging from 760 nm to 620 nm (nanometers) to pass through, and the green light filter layer allows only green light with a wavelength ranging from 580 nm to 490 nm (nanometers) to pass through. Therefore, it is impossible for visible light to pass through the black matrix formed by the overlap of the red light filter layer and the green light filter layer, such that crosstalk between sub-pixels is avoided.

A width of the light-shielding layer 301 along a first direction is greater than or equal to a width of the black matrix between adjacent sub-pixels. The first direction is a direction pointing from a center of the display region 200 towards the bezel region 300.

In some embodiments, as shown in FIG. 2, the display panel further includes a first alignment mark 102 (e.g., an alignment mark of a yellow light exposure machine) in the bezel region 300. In the first direction, a distance d1 between an edge of a side, distal from the display region 200, of the light-shielding layer 301 and an edge of a side, proximal to the display region 200, of the first alignment mark 102 is greater than a maximum size of the sub-pixel. The first direction is the direction pointing from the center of the display region 200 towards the bezel region 300. The first alignment mark 102 is formed, in some embodiments, at an outer edge position of the bezel region 300 for alignment during the formation of the first package layer 207, the first planarization layer 208, the light-shielding layer 301, the second planarization layer 209, and the second package layer 21. Therefore, in the present disclosure, an outer boundary of the orthographic projection of the light-shielding layer 301 on the substrate 100 is disposed on an inner boundary of an orthographic projection of the first alignment mark 102 on the substrate 100. That is, the light-shielding layer 301 does not cover the first alignment mark 102 formed at the outer edge position of the bezel region 300, such that the alignment effect of the first alignment mark 102 is not affected. By defining the distance between the edge of the side, distal from the display region 200, of the light-shielding layer 301 and the edge of the side, proximal to the display region 200, of the first alignment mark 102 to be greater than the maximum size of the sub-pixel, the predetermined distance is precisely controlled. In the case that the distance is too small, the difficulty of the process is too large to be precisely controlled. In some embodiments, for a circular sub-pixel, a maximum size of the sub-pixel is its diameter, and for a rectangular sub-pixel, a maximum size of the sub-pixel is its diagonal length.

In some embodiments, as shown in FIG. 2, an edge of a side, away from the display region 200, of the cover plate 204 is closer to the display region 200 compared with an edge of a side, distal from the display region 200, of the light-shielding layer 301. That is, as shown in FIG. 2, the outer boundary of the orthographic projection of the light-shielding layer 301 on the substrate 100 is outside an outer boundary of an orthographic projection of a portion, within the bezel region 300, of the cover plate 204. In this way, it is ensured that there is no longitudinal gap between the cover plate 204 and the light-shielding layer 301, and the light leakage from the periphery of the cover plate 204 is avoided, wherein the light leakage is caused by reflections of the metal wiring 101 and the second electrode layer (cathode) 205 extending to the bezel region 300 on the light exiting from the sub-pixels of the display region 200.

In some embodiments, as shown in FIG. 2, in the first direction, a distance d2 between the edge of the side, distal from the display region 200, of the light-shielding layer 301 and an edge of a side, distal from the display region 200, of the cover plate 204 is less than a distance d3 between the edge of the side, distal from the display region 200, of the light-shielding layer 301 and an edge of a side, distal from the display region 200, of the substrate 100. The first direction is the direction pointing from the center of the display region 200 towards the bezel region 300.

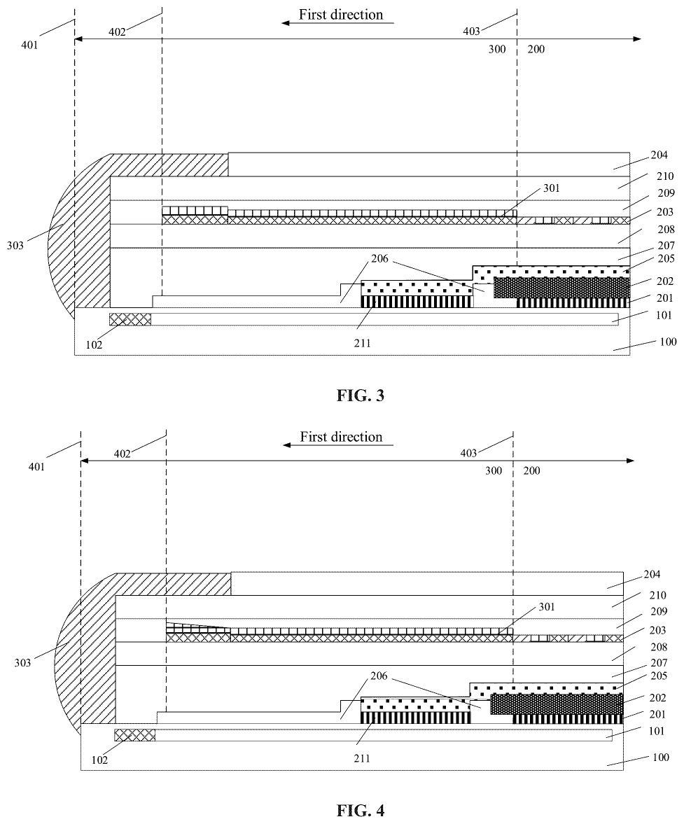

In some embodiments, as shown in FIG. 3, in a direction perpendicular to the substrate 100, the light-shielding layer 301 has an overlapping region that is overlapped with the cover plate 204, and a non-overlapping region that is not overlapped with the cover plate 204. A thickness of the overlapping region that is overlapped with the cover plate 204 is less than a thickness of the non-overlapping region. This variation in thickness is caused by the fit of the cover plate 204. A greater thickness of the non-overlapping region of the light-shielding layer 301 (i.e., a portion that extends beyond the cover plate 204) enables side light blocking, and thus the light leakage from the periphery of the cover plate 204 is avoided, wherein the light leakage is caused by reflections of the metal wiring 101 and the second electrode layer (cathode) 205 extending to the bezel region 300 on the light exiting from the sub-pixels of the display region 200.

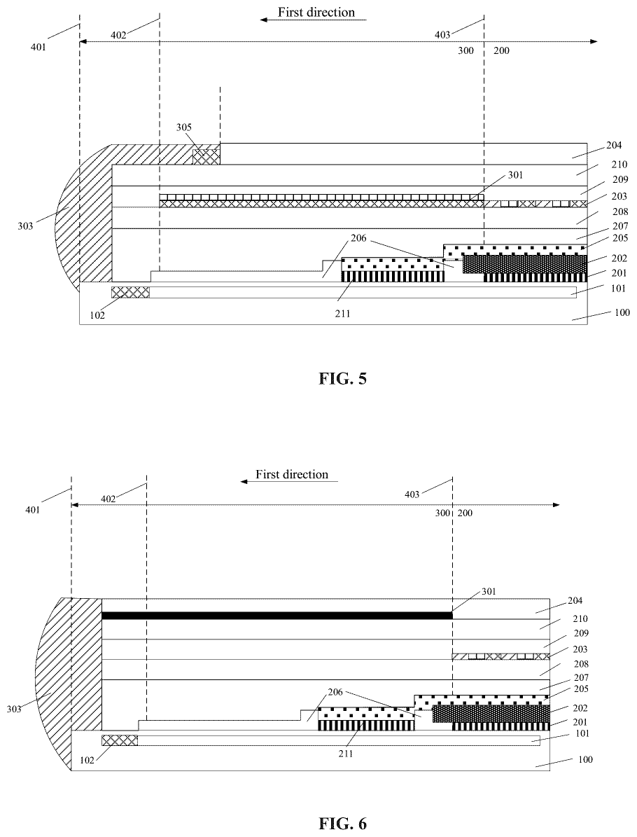

In some embodiments, as shown in FIG. 4, the thickness of the non-overlapping region of the light-shielding layer 301 in the direction perpendicular to the substrate 100 is gradually increased along the first direction, and the first direction is the direction pointing from the center of the display region 200 towards the bezel region 300. In this way, the side light blocking is realized, and the light leakage from the periphery of the cover plate 204 is avoided, wherein the light leakage is caused by reflections of the metal wiring 101 and the second electrode layer (cathode) 205 extending to the bezel region 300 on the light exiting from the sub-pixels of the display region 200.

In some embodiments, as shown in FIG. 2, the light-shielding layer 301 is a color film extension layer 301 provided in the same layer as the color film layer 203, and the color film extension layer 301 includes at least two color film layers of different colors. The color film extension layer is also referred to as a color film (CF) frame. In some embodiments, the color film extension layer 301 is formed by an overlap of a red light filter layer and a green light filter layer. The red light filtering layer allows only red light with a wavelength ranging from 760 nm to 620 nm to pass through, and the green light filter layer allows only green light with a wavelength ranging from 580 nm to 490 nm to pass through. Therefore, it is impossible for visible light to pass through the color film extension layer 301 formed by the red light filter layer and the green light filter layer, such that the function of the light-shielding layer is achieved.

In the case that the color film extension layer 301 includes two color film layers of different colors, a thickness of the color film extension layer 301 is twice a thickness of the color film layer 203. Optionally, in the direction perpendicular to the substrate 100, a thickness of a portion of the color film extension layer 301 that is overlapped with the cover plate 200 is less than a thickness of a portion corresponding to the non-overlapping region.

In some embodiments, the process of preparing the color film extension layer 301 of the bezel region 300 and the color film layer 203 of the display region 200 in the same layer includes: in some embodiments, a red light filter layer is deposited first, and the red light filter layer in the display region 200 is patterned then, a blue light filter layer is deposited, and the blue light filter layer in the display region 200 is patterned; and finally, a green light filter layer is deposited, and the green light filter layer in the display region 200 is patterned and the green light filter layer in the bezel region 300 is removed, such that the color film layer 203 and the color film extension layer 301 shown in FIG. 2 are acquired. The manner in which the color film extension layer 301 and the color film layer 203 are arranged in the same layer simplifies the process and facilitates preparation.

In some embodiments, as shown in FIG. 5, the display panel further includes a second alignment mark 305 in the bezel region 300. The second alignment mark 305 is disposed on the side, distal from the substrate 100, of the light-shielding layer 301 and is disposed in the same layer as the cover plate 204. The second alignment mark 305 is configured for alignment when affixing the cover plate 204.

In some embodiments, as shown in FIG. 5, an orthographic projection of the second alignment mark 305 on the substrate 100 is within the orthographic projection of the light-shielding layer 301 on the substrate 100 and is not overlapped with the orthographic projection of the cover plate 204 on the substrate 100. That is, the second alignment mark 305 is covered by the light-shielding layer 301. An outer edge of the second alignment mark 305 is disposed on a side, proximate to the display region 200, of an outer edge of the light-shielding layer 301, and an inner edge of the second alignment mark 305 is flush with a design position of an outer edge of the cover plate 204, which allows to use the second alignment mark 305 for alignment when affixing the cover plate 204.

In some embodiments, as shown in FIG. 2, the display panel further includes an adhesive layer 303 for package. The adhesive layer 303 covers an edge of a side, distal from the display region 200, of the bezel region 300. That is, the adhesive layer 303 is configured to package the outer edge of the bezel region 300. In this way, it is ensured that the light exiting from the display region 200 is avoided from leaking out of the periphery of the cover plate 204.

In some embodiments, as shown in FIG. 2, in conjunction with the embodiments described above, in the case that the display region 200 further includes a second package layer 210, the adhesive layer 303 is at least partially disposed on a side, distal from the substrate 100, of the second package layer 210. That is, a portion of the adhesive layer 303 is configured to fill and package a space that is left due to the fact that the cover plate 204 does not extend to the outer edge of the bezel region 300.

In some embodiments, the adhesive layer 303 abuts against the edge of the side, distal from the display region 200, of the cover plate 204.

In some embodiments, as shown in FIG. 2, there is a light-shielding overlapping region between the orthographic projection of the light-shielding layer 301 on the substrate 100 and an orthographic projection of the adhesive layer 303 on the substrate 100. In the case where the display region 200 also includes the first package layer 207, in the first direction, a width d2 of the light-shielding overlapping region between the orthographic projection of the light-shielding layer 301 on the substrate 100 and the orthographic projection of the adhesive layer 303 on the substrate 100 is greater than a target distance. The target distance is a distance d4 between the edge of the side, displat from the display region, of the light-shielding layer 301 and an edge of a side, distal from the display region, of the first package layer 207, and the first direction is the direction pointing from the center of the display region 200 towards the bezel region 300.

In some embodiments, the adhesive layer 303 configured to package the outer edge of the bezel region 300 is referred to as a sidewall dispensing adhesive. As shown in FIG. 2, an outer boundary of the cover plate 204 is at a distance from an outer boundary of the bezel region 300 illustrated by the cutting guideline 401, then the adhesive layer 303 extends to the top of the bezel region 300 to package an outer side of the cover plate 204 in addition to packaging the sidewall of the bezel region 303. Furthermore, the actual cutting is performed at other positions at the left of the line 402 defining the inner boundary of the cutting region in FIG. 2. In the case that the cutting is not performed at the cutting guideline 401, the outer boundary of the bezel region 300 shown in FIG. 2 is shifted from the cutting guideline 401 to the actual cutting line.

As shown in FIG. 6, some other embodiments of the present disclosure provide a display panel. Unlike the display panel according to the above embodiments, in this display panel provided by other embodiments, the cover plate 204 extends to an edge, distal from the display region 200, of the bezel region 300, and in the bezel region 300, the orthographic projection of the light-shielding layer 301 on the substrate 100 is consistent with the orthographic projection of the cover plate 204 on the substrate 100. That is, in the embodiments, the light-shielding layer 301 covers the entire bezel region 300. Thus, with the cooperation of the adhesive layer 303, the light exiting from the display region 200 is avoided from leaking out of the cover plate 204. In some embodiments, the light-shielding layer 301 in the embodiments is a light-shielding layer 301, that is formed on a side, facing towards the substrate, of a portion, within the bezel region 300, of the cover plate 204, and is prepared, in some embodiments, by a light-shielding material such as Cr (chromium) or carbon black.

It should be noted that, as shown in FIG. 6, the light-shielding layer 301 in the embodiments is formed, in some embodiments, on the second package layer 210. In other words, the cover plate 204 where the light-shielding layer 301 is formed is adhered, in some embodiments, by the adhesive layer, to the second package layer 210, such that the first package layer 207, the first planarization layer 208, the second planarization layer 209, and the second package layer 210 have been formed. Therefore, it is not necessary to consider whether the light-shielding layer 301 blocks the first alignment mark 102, and the light-shielding layer 301 is capable of covering the entire bezel region 300.

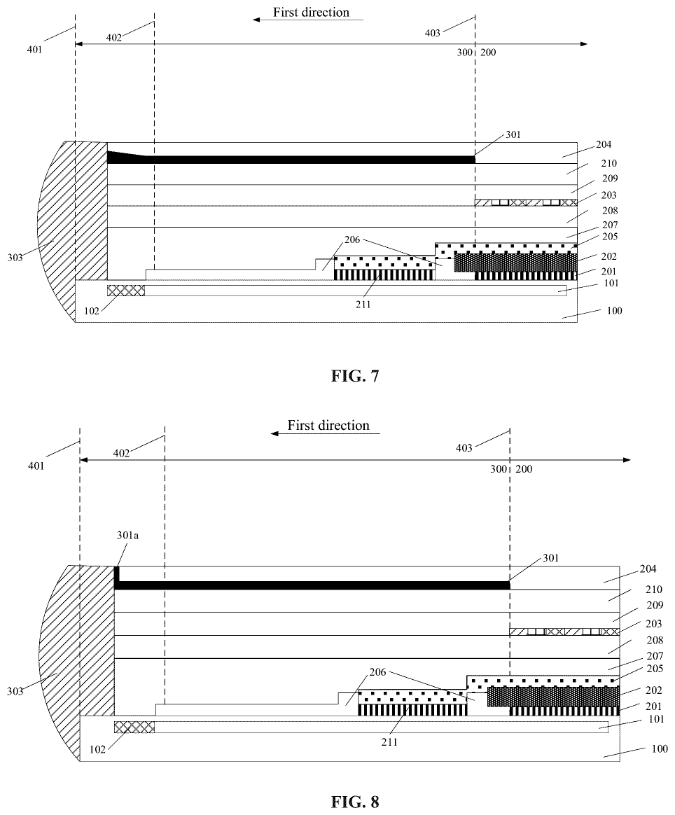

In some embodiments, as shown in FIG. 7, in the case that the bezel region also includes the first alignment mark 102, a thickness of a first portion of the light-shielding layer 301 in the direction perpendicular to the substrate 100 gradually increases along the first direction. The first portion of the light-shielding layer 301 is a portion of the light-shielding layer whose orthographic projection on the substrate 100 is consistent with the orthographic projection of the first alignment mark 102 on the substrate 100. That is, the thickness of the portion of the light-shielding layer 301 covering the first alignment mark 102 in the direction perpendicular to the substrate 100 gradually increases along the first direction. The first direction is the direction pointing from the center of the display region 200 towards the bezel region 300.

In some embodiments, as shown in FIG. 8, the display panel further includes the adhesive layer 303 for package, the display region further includes the second package layer 210, and the adhesive layer 303 is partially disposed on the side, distal from the substrate 100, of the second package layer 210. In this case, the light-shielding layer 301 includes an edge light-shielding layer 301a that extends between a first edge of the cover plate 204 and the adhesive layer 303. The first edge is an edge of a side, distal from the display region 100, of the cover plate 204. In this way, the light exiting from the display region 200 is avoided from leaking out of the periphery of the cover plate 204.

In some embodiments, as shown in FIG. 8, a thickness of the portion of the light-shielding layer 301 that extends between the edge of the side, distal from the display region 200, of the cover plate 204 and the adhesive layer 303 (i.e., the edge light-shielding layer 301a of the light-shielding layer 301 perpendicular to the substrate 100) in a direction parallel to the substrate 100 is less than a thickness of a rest of the light-shielding layer 301 (i.e., a portion of the light-shielding layer 301 that is parallel to the substrate 100 except for the edge light-shielding layer 301a) in the direction perpendicular to the substrate 100.

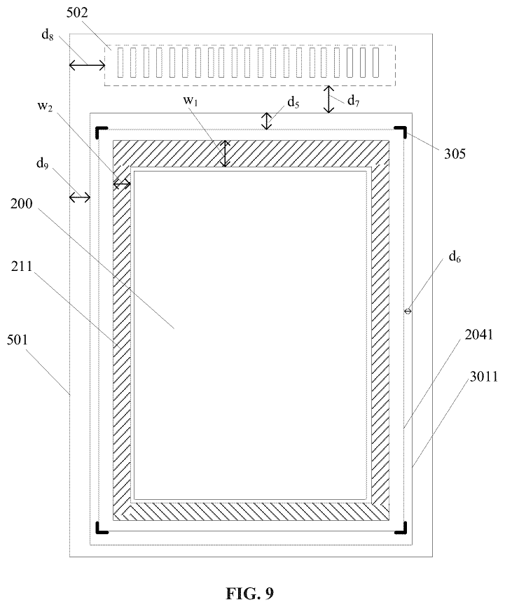

As shown in FIG. 9, some other embodiments of the present disclosure provide a display device including the display panel as described above.

It should be noted that FIG. 9 shows a case in which “the edge of the side, distal from the display region 200, of the cover plate 204 is closer to the display region 200 compared with the edge of the side, distal from the display region 200, of the light-shielding layer 301” used in the first embodiments. In FIG. 9, 501 is the edge, distal from the display region 200, of the substrate 100 of the display panel, i.e., an outer edge line of the substrate 100. FIG. 9 also shows the display region 200 of the display panel, the cathode ring 211, the outer edge 2041 of the cover plate 204, the outer edge 3011 of the light-shielding layer 301, and the second alignment mark 305.

In some embodiments, as shown in FIG. 9, the display device further includes a bonding region 502, the display panel is in a substantially rectangular shape (e.g., rectangular), and the bonding region 502 is disposed on a short side of the display panel.

In some embodiments, in a first direction, a first distance d5 of the display panel is greater than a second distance d6. The first distance d5 is a distance between an edge of a side, distal from the display region 200, of the light-shielding layer 301 in the bezel region 300 on the short side of the display panel and the edge of the side, distal from the display region 204, of the cover plate 204 (i.e., a minimum linear distance between an edge line 2041 in the upper and lower sides and an edge line 3011 in FIG. 9). The second distance d6 is a distance between an edge of a side, distal from the display region 200, of the light-shielding layer 301 in the bezel region 300 on the long side of the display panel and the edge of side, distal from the display region 200, of the cover plate 204 (i.e., a minimum linear distance between an edge line 2041 on the left and right sides and an edge line 3011 in FIG. 9). Referring to FIG. 2, the first direction is the direction pointing from the center of the display region 200 towards the bezel region 300. In this way, the bonding is performed on the short side of the display panel, which has a wider light-shielding layer 301, such that the stress on the package layer in the display panel is relieved, and the fracture during bonding is avoided.

In some embodiments, as shown in FIG. 9, the second alignment mark 305 is an L-shaped alignment mark disposed at four corners of the substantially rectangle. A width of the second alignment mark 305, in the first direction, is less than or equal to the minimum distance (i.e., d6) between the edge of the side, distal from the display region 200, of the light-shielding layer 301 and the edge of the side, distal from the display region 200, of the cover plate 204, such that the orthographic projection of the second alignment mark 305 on the substrate 100 is within the orthographic projection of the light-shielding layer 301 on the substrate 100 and is not overlapped with the orthographic projection of the cover plate 204 on the substrate 100. The first direction is the direction pointing from the center of the display region 200 towards the bezel region 300.

In some embodiments, in the case that the bezel region 300 further includes a cathode ring 211 surrounding the display region 200, in the first direction, a width w1 of the cathode ring 211 in the bezel region 300 on the short side, proximal to the bonding region 502, of the display panel (i.e., a width of the cathode ring 211 on the upper side in FIG. 9) is greater than a width w2 of the cathode ring 211 in the bezel region 300 on other sides (i.e., the widths of the cathode rings 211 on the lower, left, and right sides in FIG. 9). Referring to FIG. 2, the first direction is the direction pointing from the center of the display region 200 towards the bezel region 300. In this way, the light leakage is avoided, and the stress is relieved, which avoids fracture during bonding.

In some embodiments, in the first direction, the distance d5 and d6 (i.e., the minimum linear distance between the edge line 2041 and the edge line 3011 in FIG. 9) between the edge of the side, distal from the display region 200, of the light-shielding layer 301 in the bezel region 300 of the display panel and the edge of the side, distal from the display region 200, of the cover plate 204 is less than a minimum distance d7 (e.g., a minimum linear distance between the lower side of the bonding region 502 and the upper side of the edge line 3011 in FIG. 9) between the bonding region 502 and the light-shielding layer 301.

In some embodiments, a minimum distance d8 (e.g., a minimum linear distance between the left side of the bonding region 502 and the left side of the edge line 501 in FIG. 9) from the edge, proximal to the long side of the display panel, of the bonding region 502 to the edge 501 of the side, distal from the display region 200, of the substrate 100 is greater than a minimum distance d9 (e.g., a minimum linear distance between the left edge line 3011 of the light-shielding layer 301 and the left side of the edge line 501 in FIG. 9) from the edge 3011, proximal to the long side of the display panel, of the light-shielding layer 301 to the edge 501 of the side, distal from the display region 200, of the substrate 100.

The display device according to the embodiments may be a smartphone, a tablet computer, a television, a monitor, a laptop computer, a digital photo frame, a navigator, and any other product or component having a display function, which is not limited herein.

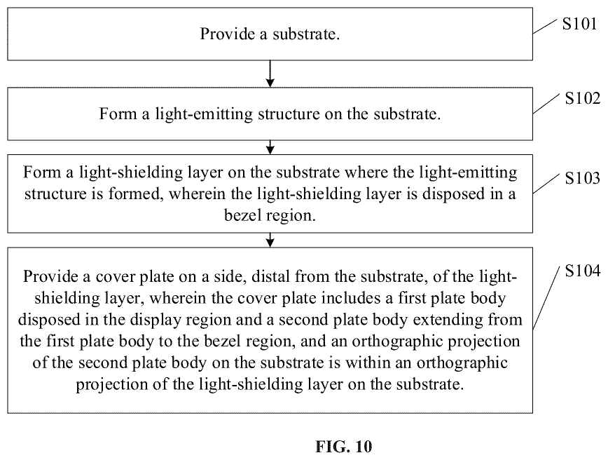

As shown in FIG. 10, some other embodiments of the present disclosure provide a method for preparing the display panel according to the above embodiments. The method includes the following steps.

In S101, a substrate is provided, wherein the substrate includes a display region and a bezel region, the bezel region surrounding the display region.

In S102, a light-emitting structure is formed on the substrate.

In S103, a light-shielding layer is formed on the substrate where the light-emitting structure is formed, wherein the light-shielding layer is disposed in the bezel region.

In S104, a cover plate is provided on a side, distal from the substrate, of the light-shielding layer, wherein the cover plate includes a first plate body disposed in the display region and a second plate body extending from the first plate body to the bezel region, and an orthographic projection of the second plate body on the substrate is within the orthographic projection of the light-shielding layer on the substrate.

Obviously, the above embodiments of the present disclosure are only examples for the purpose of clearly illustrating the present disclosure and are not intended to construct any limitation to the embodiments of the present disclosure. For those skilled in the art, different forms of changes or variations can be made on the basis of the above description, and it is not possible to exhaust all the embodiments herein. Any obvious variations or changes that are derived from the technical solution of this application remain within the scope of protection of this application.

1. A display panel, comprising:
a substrate, wherein the substrate comprises a display region and a bezel region, the bezel region surrounding the display region;
a light-emitting structure, wherein the light-emitting structure is disposed on the substrate;
a light-shielding layer, wherein the light-shielding layer is disposed on the substrate where the light-emitting structure is disposed, and the light-shielding layer is disposed in the bezel region; and
a cover plate, wherein the cover plate is disposed on a side, distal from the substrate, of the light-light-shielding layer, and the cover plate comprises a first plate body disposed in the display region and a second plate body extending from the first plate body to the bezel region, an orthographic projection of the second plate body on the substrate being within an orthographic projection of the light-shielding layer on the substrate.

2. The display panel according to claim 1, further comprising: a color film layer, wherein the color film layer is disposed in the display region, and the color film layer extends to a border of the bezel region and the display region.

3. The display panel according to claim 2, wherein the light-emitting structure comprises a driver circuit layer and a light-emitting layer, wherein the driver circuit layer comprises a metal wiring, and the light-emitting layer comprises a first electrode layer, a pixel definition layer, a light-emitting function layer, and a second electrode layer that are stacked;
wherein the metal wiring comprises an edge metal wiring disposed in the bezel region, an orthographic projection of the edge metal wiring on the substrate being within the orthographic projection of the light-shielding layer on the substrate.

4. The display panel according to claim 2, further comprising: a first package layer and a first planarization layer that are disposed between the light-emitting layer and the color film layer;
wherein the first package layer and the first planarization layer are successively stacked along a direction away from the substrate, and the first package layer and the first planarization layer extend to the bezel region.

5. The display panel according to claim 4, wherein the light-shielding layer is disposed on a side, distal from the substrate, of the first planarization layer.

6. The display panel according to claim 5, wherein the light-shielding layer is a color film extension layer arranged in a same layer as the color film layer, and the light-shielding layer comprises at least two layers of the color film layer of different colors.

7. The display panel according to claim 5, further comprising: a first alignment mark in the bezel region, wherein the light-emitting structure comprises a plurality of sub-pixels in the display region;
wherein in a first direction, a distance between an edge of a side, distal from the display region, of the light-shielding layer and an edge of a side, proximal to the display region, of the first alignment mark is greater than a maximum size of the sub-pixel, the first direction being a direction pointing from a center of the display region towards the bezel region.

8. The display panel according to claim 4, further comprising: a second planarization layer and a second package layer that are disposed between the color film layer and the cover plate; wherein
the second planarization layer and the second package layer are disposed in the display region, the second planarization layer and the second package layer are successively stacked along the direction away from the substrate, and both the second planarization layer and the second package layer extend to the bezel region; and
the light-shielding layer is disposed on a side, distal from the substrate, of the second package layer.

9. The display panel according to claim 8, further comprising: a second alignment mark in the bezel region, wherein the second alignment mark is disposed on the side, distal from the substrate, of the light-shielding layer, and the second alignment mark is disposed on a same layer as the cover plate.

10. The display panel according to claim 2, wherein the light-emitting structure comprises a plurality of sub-pixels in the display region, and the display panel further comprises a black matrix disposed between adjacent sub-pixels in the plurality of sub-pixels; wherein
the black matrix is formed by overlaying color films of different colors; and
a width of the light-shielding layer along a first direction is greater than or equal to a width of the black matrix between the adjacent sub-pixels, the first direction being a direction pointing from a center of the display region towards the bezel region.

11. The display panel according to claim 10, wherein in a case that the display panel comprises the second alignment mark in the bezel region, an orthographic projection of the second alignment mark on the substrate is within the orthographic projection of the light-shielding layer on the substrate, and the orthographic projection of the second alignment mark on the substrate is not overlapped with an orthographic projection of the cover plate on the substrate.

12. The display panel according to claim 1, further comprising: an adhesive layer for package, wherein the adhesive layer covers an edge of a side, distal from the display region, of the bezel region.

13. The display panel according to claim 12, wherein in a case that the display region further comprises the second package layer, the adhesive layer is at least partially disposed on the side, distal from the substrate, of the second package layer.

14. The display panel according to claim 13, wherein the light-shielding layer comprises an edge light-shielding layer extending between a first edge of the cover plate and the adhesive layer, the first edge being an edge of a side, distal from the display region, of the cover plate.

15. (canceled)

16. The display panel according to claim 13, wherein the adhesive layer abuts against an edge of a side, distal from the display region, of the cover plate;
wherein a light-shielding overlapping region is present between the orthographic projection of the light-shielding layer on the substrate and an orthographic projection of the adhesive layer on the substrate, and in a case that the display region further comprises the first package layer, in a first direction, a width of the light-shielding overlapping region is greater than a target distance, wherein the target distance is a distance between the edge of the side, distal from the display region, of the light-shielding layer and an edge of a side, distal from the display region, of the first package layer, and the first direction is a direction pointing from a center of the display region towards the bezel region.

17. (canceled)

18. The display panel according to claim 1, wherein in a first direction, a distance between the edge of the side, distal from the display region, of the light-shielding layer and an edge of a side, distal from the display region, of the cover plate is less than a distance between the edge of the side, distal from the display region, of the light-shielding layer and an edge of a side, distal from the display region, of the substrate, the first direction being a direction pointing from a center of the display region towards the bezel region.

19. The display panel according to claim 1, wherein in a direction perpendicular to the substrate, the light-shielding layer comprises an overlapping region overlapped with the cover plate and a non-overlapping region not overlapped with the cover plate, a thickness of the overlapping regions being less than a thickness of the non-overlapping region, wherein the thickness of the non-overlapping region in the direction perpendicular to the substrate gradually increases along a first direction, the first direction being a direction pointing from a center of the display region towards the bezel region.

20. (canceled)

21. The display panel according to claim 1, wherein
the cover plate extends to an edge, distal from the display region, of the bezel region; and
in the bezel region, the orthographic projection of the light-shielding layer on the substrate is consistent with an orthographic projection of the cover plate on the substrate.

22.-23. (canceled)

24. A display device, comprising: a display panel; wherein the display panel comprises:
a substrate, wherein the substrate comprises a display region and a bezel region, the bezel region surrounding the display region;
a light-emitting structure, wherein the light-emitting structure is disposed on the substrate;
a light-shielding layer, wherein the light-shielding layer is disposed on the substrate where the light-emitting structure is disposed, and the light-shielding layer is disposed in the bezel region; and
a cover plate, wherein the cover plate is disposed on a side, distal from the substrate, of the light-light-shielding layer, and the cover plate comprises a first plate body disposed in the display region and a second plate body extending from the first plate body to the bezel region, an orthographic projection of the second plate body on the substrate being within an orthographic projection of the light-shielding layer on the substrate.

25.-29. (canceled)

30. A method for preparing a display panel, applicable to preparing the display panel as defined in claim 1, the method comprising:
providing a substrate, wherein the substrate comprises a display region and a bezel region, the bezel region surrounding the display region;
forming a light-emitting structure on the substrate;
forming a light-shielding layer on the substrate where the light-emitting structure is formed, wherein the light-shielding layer is disposed in the bezel region; and
disposing a cover plate on a side, distal from the substrate, of the light-shielding layer, wherein the cover plate comprises a first plate body disposed in the display region and a second plate body extending from the first plate body to the bezel region, an orthographic projection of the second plate body on the substrate being within an orthographic projection of the light-shielding layer on the substrate.
